(19) United States
(12) Patent Application Publication
(10) Pub. No.: US 2026/0150625 A1
(43) Pub. Date: May 28, 2026

(54) SEMICONDUCTOR DEVICE AND MANUFACTURING METHOD THEREOF

(71) Applicant: NANYA TECHNOLOGY CORPORATION, New Taipei City (TW)

(72) Inventors: Ming Hsun WU, New Taipei City (TW); Yu-Yu WU, New Taipei City (TW)

(21) Appl. No.: 18/963,587

(22) Filed: Nov. 28, 2024

(51) Int. Cl. H01L 21/66; H01L 23/528; H01L 29/40

(52) U.S. Cl. CPC H10P 74/207; H10D 64/01; H10W 20/43

(57) ABSTRACT

A manufacturing method of a semiconductor device includes forming a plurality of photoresist strips on a substrate, in which an opening is formed in each of the photoresist strips; forming a plurality of contacts in the openings of the photoresist strips, in which an outer contour of each of the contacts is a string shape; and using the photoresist strips to form a plurality of bit lines.

### BACKGROUND

### Field of Invention

The present disclosure relates to a semiconductor device and a manufacturing method of a semiconductor device.

### Description of Related Art

In the final stage of the manufacturing of memory cells, a wafer acceptance test (WAT) is often executed to test the electrical properties of the wafer. However, while the manufacturing process of the wafer is changed and self-aligned double patterning (SADP) is introduced, the test becomes harder to execute since there are too many target active area (AA) due to mask shift. This kind of mask shift is hard to control or avoid, which means a new test method is in need.

### SUMMARY

One aspect of the present disclosure provides a manufacturing method of a semiconductor device.

According to one embodiment of the present disclosure, a manufacturing method of a semiconductor device includes forming a plurality of photoresist strips on a substrate, in which an opening is formed in each of the photoresist strips; forming a plurality of contacts in the openings of the photoresist strips, in which an outer contour of each of the contacts is a string shape; and using the photoresist strips to form a plurality of bit lines.

In some embodiment of the present disclosure, the manufacturing method of the semiconductor device further includes forming a plurality of active areas on the substrate.

In some embodiment of the present disclosure, each of the contacts connects two of the active areas.

In some embodiment of the present disclosure, each of the active areas connects two of the contacts.

In some embodiment of the present disclosure, the manufacturing method of the semiconductor device further includes forming a peripheral contact on the substrate.

In some embodiment of the present disclosure, the peripheral contact

### ELECTRICALLY CONNECTS THE CONTACTS.

In some embodiment of the present disclosure, the manufacturing method of the semiconductor device further includes measuring an active area resistance through the contacts.

Another aspect of the present disclosure provides a manufacturing method of a semiconductor device.

According to one embodiment of the present disclosure, a manufacturing method of a semiconductor device includes forming a plurality of active areas on a substrate; using a plurality of photoresist strips to form a plurality of contacts, wherein an opening is formed in each of the photoresist strips, an outer contour of each of the contacts is a string shape; and using the photoresist strips to form a plurality of bit lines.

In some embodiment of the present disclosure, each of the contacts connects two of the active areas.

In some embodiment of the present disclosure, each of the active areas connects two of the contacts.

In some embodiment of the present disclosure, the manufacturing method of the semiconductor device further includes forming a peripheral contact on the substrate.

In some embodiment of the present disclosure, the peripheral contact electrically connects the contacts.

In some embodiment of the present disclosure, the manufacturing method of the semiconductor device further includes measuring an active area resistance through the contacts.

Another aspect of the present disclosure provides a semiconductor device.

According to one embodiment of the present disclosure, a semiconductor device includes a substrate, a plurality of active areas, a plurality of contacts, a plurality of bit lines and a plurality of peripheral contacts. The active areas are located on the substrate. The contacts are located on the active areas and electrically connecting the active areas, in which an outer contour of each of the contacts is a string shape. The bit lines are located on the active areas. The peripheral contacts are located on the active areas.

In some embodiment of the present disclosure, each of the contacts connects two of the active areas.

In some embodiment of the present disclosure, each of the active areas connects two of the contacts.

In some embodiment of the present disclosure, the peripheral contacts electrically connect the contacts and the active areas.

In the aforementioned embodiments of the present disclosure, since the string-shaped contacts are formed in the manufacturing method of the semiconductor device, when executing the wafer acceptance test, the test probes can electrically connect two of the peripheral contacts. Then, a single conductive path formed by peripheral contacts, string-shaped contacts and active areas are formed and can be used to perform wafer acceptance test, which makes the test easier and ensures the yield.

### BRIEF DESCRIPTION OF THE DRAWINGS

FIG. 1 to FIG. 4 are top views of intermediate steps of the manufacturing method of the semiconductor device according to one embodiment of the present disclosure.

FIG. 5 is a top view of the semiconductor device at the step of FIG. 4.

FIG. 6 is a top view of intermediate steps of the manufacturing method of the semiconductor device according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, or “substantially” used herein include the value and an average of values within an acceptable tolerance range of a specific value determined by one of ordinary skill in the art, in consideration of a specific quantity of measurement and measurement related errors discussed (that is, limitation of a measuring system). For example, “about” may indicate within one or more standard deviation of the value, or within ±30%, ±20%, ±10%, or ±5% of the value. Further, for the terms “about”, “approximately”, or “substantially” used herein, a relatively acceptable tolerance range or standard deviation may be selected based on optical properties, etching properties, or other properties, rather than one standard is applied to all properties.

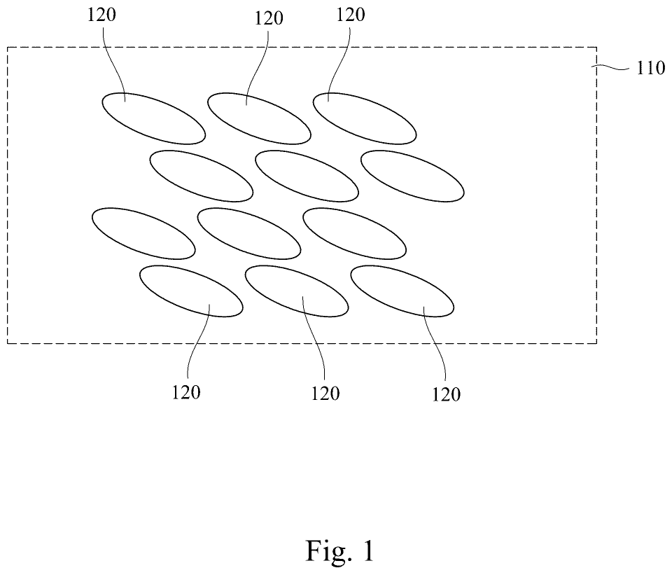

FIG. 1 to FIG. 4 are top views of intermediate steps of the manufacturing method of the semiconductor device 100 according to one embodiment of the present disclosure. Refer to FIG. 1, first, forming a plurality of active areas 120 on a substrate 110. The numbers of the active areas 120 are not limited to the number shown in FIG. 1. In some embodiments, the shape of the active areas 120 is an ellipse. In some embodiments, the shape of the active areas 120 is a circle, a square, or any suitable shape. In some embodiments, the arrangement of the active areas 120 can be arranged in an array, or other suitable arrangements that can maximize the density of the active areas 120.

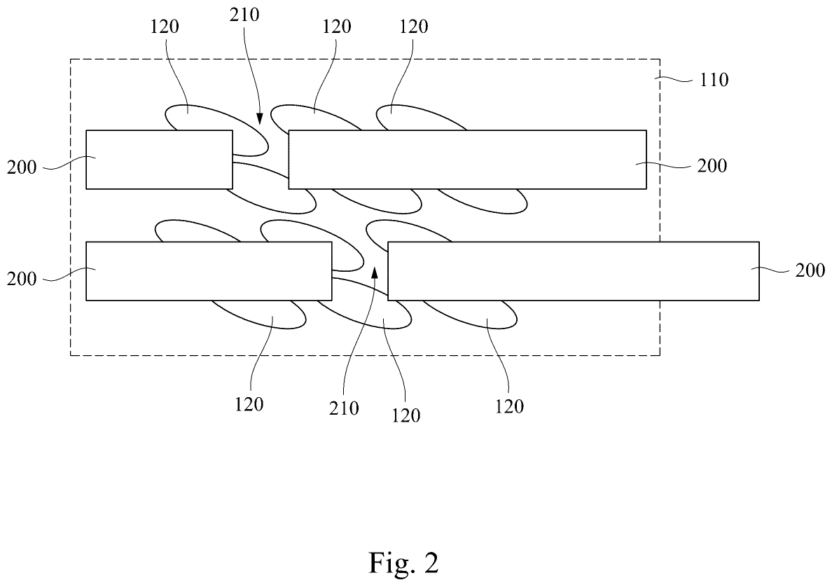

Refer to FIG. 2, thereafter, forming a plurality of photoresist strips 200 on the substrate 110, in which an opening 210 is formed in each of the photoresist strips 200. In some embodiments, the photoresist strips 200 are bit line (BL) profile resist, since the photoresist strips 200 are used to form the bit lines in later process. In some embodiments, the photoresist strips 200 are coated on the substrate evenly, and then undergo an exposure and a development process. In some embodiments, the arrangement of the openings 210 of the photoresist strips 200 are arranged such that the openings 210 are all aligned in a line. The extension direction of the line can be parallel to the long axis of the ellipse-shaped active area 120, or have an included angle in-between.

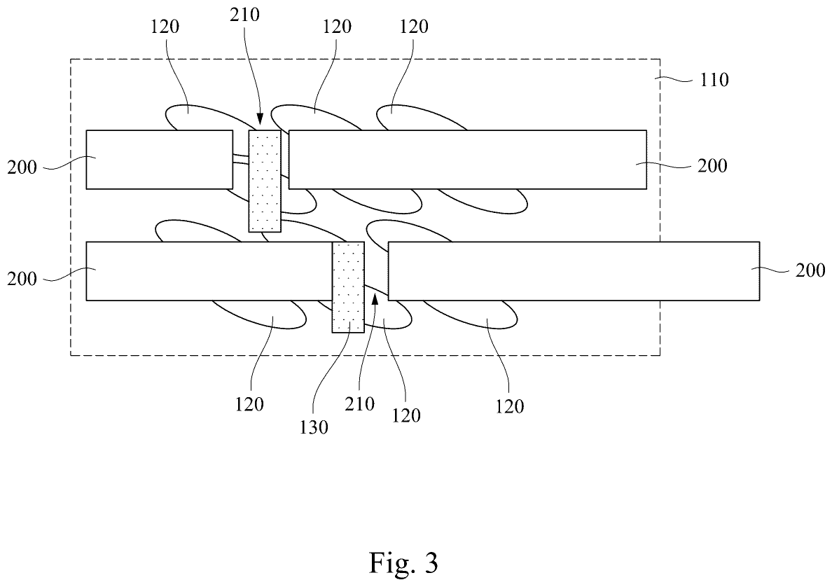

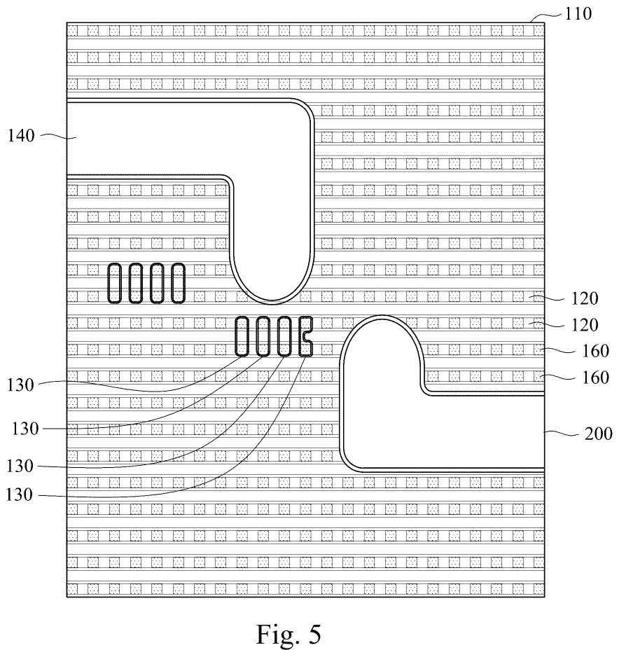

Refer to FIG. 3, thereafter, forming a plurality of contacts 130 in the openings 210 of the photoresist strips 200, in which an outer contour of each of the contacts 130 is a string shape. The contacts 130 are located on the active area 120 and electrically connect the active area 120. In some embodiments, the contacts 130 are contact pads of the active areas 120. In some embodiments, each of the contacts 130 connects two of the active areas 120. In some embodiments, each of the active areas 120 connects two of the contacts 130. Since each of the contacts 130 connects two of the active areas 120 and each of the active areas 120 connects two of the contacts 130, a conductive path of contact-AA-contact . . . AA-contact is formed after the contacts 130 are formed on the active areas 120. In some embodiments, the material of the contacts 130 can include conductive materials such as copper (Cu), silver (Ag), gold (Au), an alloy thereof, a combination thereof, or the like. In some embodiments, the contacts 130 can be formed through a deposition process. Noteworthy, other contact pads that are not string-shaped are also formed in this step, which will be described in FIG. 5.

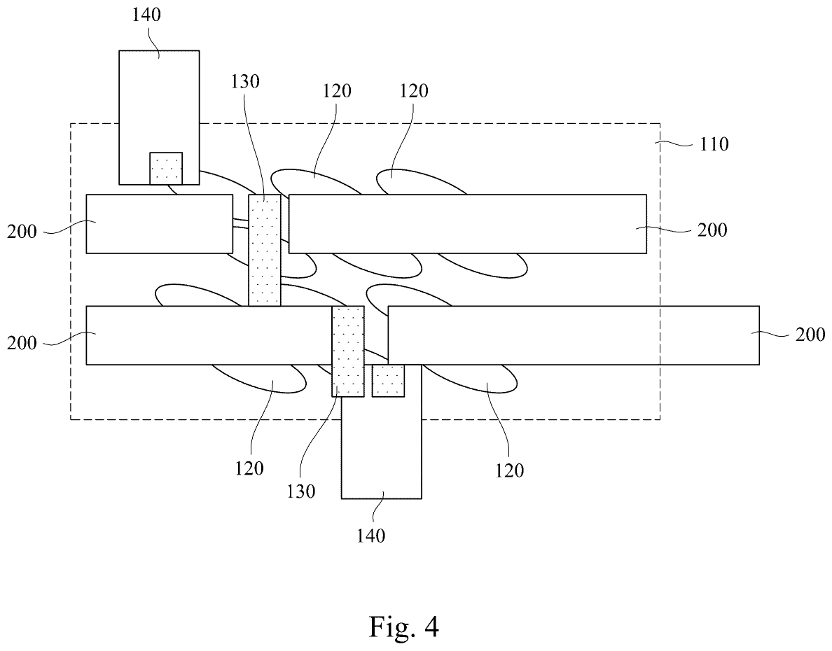

Refer to FIG. 4, thereafter, forming peripheral contacts 140 on the substrate 110. The peripheral contacts 140 are located on the contact 130 at the outermost of the substrate 110 and electrically connect the contact 130 at the outermost of the substrate 110, such that the peripheral contacts 140 electrically connect the conductive path mentioned above. In FIG. 4, only two peripheral contacts 140 are shown, but in real applications, more peripheral contacts 140 can be formed. The purpose of the peripheral contacts 140 are to connect the test probe of the active area (AA) resistance test, such that the wafer acceptance test can be performed.

FIG. 5 is a top view of the semiconductor device at the step of FIG. 4. Refer to FIG. 5, after the step of forming the peripheral contacts 140, measuring an active area resistance through the contacts 130. Noteworthy, the measurement only use the string-shaped contacts 130, which are in the conductive path mentioned above. Other contact pads 160 that are not string shaped are for later process to electrically connect to circuits such as bit lines, word lines, or other peripheral circuits. In some embodiments, the measurement of the active area resistance is measuring through a four-terminal sensing method, but the disclosure is not limited to that. In some embodiments, two of the probes of the four-terminal sensing method electrically connect the peripheral contacts 140 in FIG. 5.

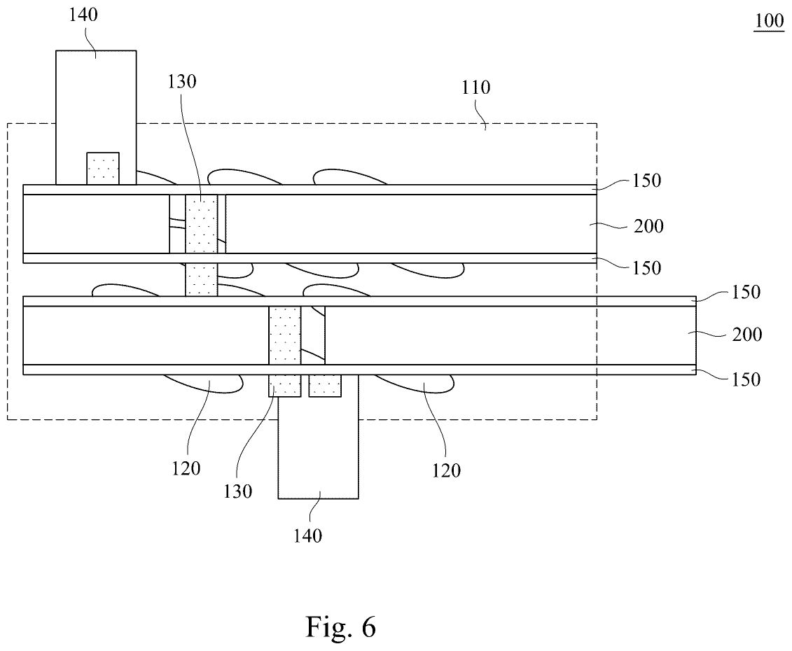

FIG. 6 is a top view of intermediate steps of the manufacturing method of the semiconductor device 100 according to one embodiment of the present disclosure. Refer to FIG. 6, thereafter, using the photoresist strips 200 to form a plurality of bit lines 150. After this step, the semiconductor device 100 is manufactured. The bit lines 150 are located on the active areas 120 and electrically connect the active areas 120. Noteworthy, although there are openings 210 in the photoresist strips 200, the bit lines 150 formed are continuous. In some embodiments, the bit lines 150 are formed on the two sides of the photoresist strips 200, such that each photoresist strip 200 can form two bit lines 150. In some embodiments, word lines (not shown) are formed after this step, which are perpendicular to the extension direction of the bit lines 150.

In summary, since the string-shaped contacts 130 are formed in the manufacturing method of the semiconductor device 100, when executing the wafer acceptance test, the test probes can electrically connect two of the peripheral contacts 140. Then, a single conductive path formed by peripheral contacts 140, string-shaped contacts 130 and active areas 120 are formed and can be used to perform wafer acceptance test, which makes the test easier and ensures the yield.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A manufacturing method of a semiconductor device, comprising:
forming a plurality of photoresist strips on a substrate, wherein an opening is formed in each of the photoresist strips;
forming a plurality of contacts in the openings of the photoresist strips, wherein an outer contour of each of the contacts is a string shape; and
using the photoresist strips to form a plurality of bit lines.

2. The manufacturing method of the semiconductor device of claim 1, further comprising:
forming a plurality of active areas on the substrate.

3. The manufacturing method of the semiconductor device of claim 2, wherein each of the contacts connects two of the active areas.

4. The manufacturing method of the semiconductor device of claim 2, wherein each of the active areas connects two of the contacts.

5. The manufacturing method of the semiconductor device of claim 1, further comprising:
forming a peripheral contact on the substrate.

6. The manufacturing method of the semiconductor device of claim 4, wherein the peripheral contact electrically connects the contacts.

7. The manufacturing method of the semiconductor device of claim 1, further comprising:
measuring an active area resistance through the contacts.

8. A manufacturing method of a semiconductor device, comprising:
forming a plurality of active areas on a substrate;
using a plurality of photoresist strips to form a plurality of contacts, wherein an opening is formed in each of the photoresist strips, an outer contour of each of the contacts is a string shape; and
using the photoresist strips to form a plurality of bit lines.

9. The manufacturing method of the semiconductor device of claim 8, wherein each of the contacts connects two of the active areas.

10. The manufacturing method of the semiconductor device of claim 8, wherein each of the active areas connects two of the contacts.

11. The manufacturing method of the semiconductor device of claim 8, further comprising:
forming a peripheral contact on the substrate.

12. The manufacturing method of the semiconductor device of claim 11, wherein the peripheral contact electrically connects the contacts in the openings of the bit lines.

13. The manufacturing method of the semiconductor device of claim 8, further comprising:
measuring an active area resistance through the contacts.

14. A semiconductor device, comprising:
a substrate;
a plurality of active areas located on the substrate;
a plurality of contacts located on the active areas and electrically connecting the active areas, wherein an outer contour of each of the contacts is a string shape;
a plurality of bit lines located on the active areas; and
a plurality of peripheral contacts located on the active areas.

15. The semiconductor device of claim 14, wherein each of the contacts connects two of the active areas.

16. The semiconductor device of claim 14, wherein each of the active areas connects two of the contacts.

17. The semiconductor device of claim 14, wherein the peripheral contacts electrically connects the contacts and the active areas.

18. The semiconductor device of claim 14, wherein two of the peripheral contacts electrically connect each other through the active areas and the contacts.
